(19) United States
(12) Patent Application Publication
(10) Pub. No.: US 2025/0218723 A1
(43) Pub. Date: Jul. 3, 2025

(54) SUBSTRATE SUPPORT DEVICE AND METHOD OF PREVENTING OCCURRENCE OF ARCING

(71) Applicant: SEMES CO., LTD., Cheonan-si (KR)

(72) Inventors: Soon Cheon CHO, Cheonan-si (KR); Ji Chul KANG, Cheonan-si (KR); Kyung Hwa JUNG, Cheonan-si (KR); Dong Uk KIM, Cheonan-si (KR)

(73) Assignee: SEMES CO., LTD., Cheonan-si (KR)

(21) Appl. No.: 19/004,238

(22) Filed: Dec. 28, 2024

(30) Foreign Application Priority Data
Dec. 28, 2023 (KR) 10-2023-0193987

(51) Int. Cl. H01J 37/32; H01J 37/34

(52) U.S. Cl. CPC H01J 37/32055; H01J 37/32816; H01J 37/32954; H01J 37/3435

(57) ABSTRACT

Disclosed are a substrate support device and a method of preventing the occurrence of arcing. Discharge voltage is controlled by forming flow of arc control gas in an upper portion of the substrate support device and controlling the pressure of the arc control gas, thereby preventing the occurrence of arcing.

### CROSS-REFERENCE TO THE RELATED APPLICATION

The present application claims priority to and the benefit of Korean Patent Application No. 10-2023-0193987, filed on Dec. 28, 2023, in the Korean Intellectual Property Office, the entire disclosure of which is incorporated herein by reference.

### BACKGROUND

### 1. Field

The present disclosure relates to a substrate support device and a method of preventing the occurrence of arcing, and more particularly, to technology for controlling discharge voltage by forming flow of arc control gas in an upper portion of a substrate support device and controlling the pressure of the arc control gas, thereby preventing the occurrence of arcing.

### 2. Description of the Related Art

In general, semiconductor devices are formed through multiple processes, such as a process of depositing predetermined materials on a wafer and a process of etching the same. Each of these processes is performed in a chamber, which is a sealed container that needs to maintain a controlled work environment. A substrate support device configured to fix a wafer is usually mounted in the chamber. Such a substrate support device supports a wafer loaded in the chamber.

A substrate is placed on the substrate support device, and a deposition or etching process is performed on the substrate using plasma. If a conductive material remains on an edge portion of the substrate during plasma processing, an accumulated charge is rapidly transferred using the conductive material as a medium, which causes arcing.

In particular, when refrigerant for cooling flows through an upper portion of the substrate support device in order to cool the substrate, expansion and contraction occur in the substrate support device due to change in temperature. This causes change in distance between electrodes and change in pressure, leading to the occurrence of arcing on the lower portion of an electrostatic-chuck plate.

Such arcing may damage not only the substrate but also the entirety of a process line.

### SUMMARY

The present disclosure has been made to solve the above problems, and it is an object of the present disclosure to provide technology for controlling discharge voltage by forming flow of arc control gas in an upper portion of a substrate support device and controlling the pressure of the arc control gas, thereby preventing the occurrence of arcing.

In particular, it is another object of the present disclosure to prevent the occurrence of arcing on a lower portion of an electrostatic-chuck plate due to change in distance between electrodes and change in pressure caused by expansion and contraction of the substrate support device due to change in temperature when refrigerant flows through an upper portion of the substrate support device in order to cool the substrate.

It is still another object of the present disclosure to provide a method of preventing the occurrence of arcing regardless of use of high power and low frequency.

The objects to be accomplished by the disclosure are not limited to the above-mentioned objects, and other objects and advantages not mentioned herein may be understood from the following description.

In accordance with an aspect of the present disclosure, the above and other objects can be accomplished by the provision of a substrate support device including an electrostatic-chuck plate configured to allow a substrate to be seated thereon and attract and support the substrate using electrostatic force, an electrode plate disposed under the electrostatic-chuck plate, a first arc control gas flow path formed between the electrostatic-chuck plate and the electrode plate, an arc control gas supply unit configured to supply arc control gas to the first arc control gas flow path, and a controller configured to control pressure of the arc control gas flowing through the first arc control gas flow path to prevent the occurrence of arcing.

Further, the electrode plate may have a heat transfer medium path formed therein to supply a heat transfer medium to a lower surface of the substrate and a cooling path formed therein to allow refrigerant for cooling of the substrate and the electrostatic-chuck plate to flow therethrough.

In an embodiment, the arc control gas supply unit may supply clean dry air (CDA) as the arc control gas.

In addition, the substrate support device may further include an insulator plate disposed under the electrode plate and a second arc control gas flow path formed between the electrode plate and the insulator plate. The arc control gas supply unit may supply arc control gas to the second arc control gas flow path, and the controller may control pressure of the arc control gas flowing through the second arc control gas flow path to prevent the occurrence of arcing.

In one example, the substrate support device may further include an arc control gas line connected to the first arc control gas flow path to supply arc control gas from the arc control gas supply unit to the first arc control gas flow path and a pressure control valve disposed on the arc control gas line to control pressure of the arc control gas.

Here, the pressure control valve may include a relief valve.

In addition, the substrate support device may further include a heater disposed on the arc control gas line to control temperature of the arc control gas.

In one example, the controller may control the pressure control valve and the heater based on an arcing occurrence profile so that the arc control gas is controlled in temperature and supplied to the first arc control gas flow path and so that pressure of the arc control gas flowing through the first arc control gas flow path is controlled to a positive pressure.

In one example, the first arc control gas flow path may include a peripheral arc control gas flow path formed corresponding to a peripheral area of the electrostatic-chuck plate, an intermediate arc control gas flow path formed corresponding to an intermediate area of the electrostatic-chuck plate, and a central arc control gas flow path formed corresponding to a central area of the electrostatic-chuck plate.

In one example, the substrate support device may further include a peripheral arc control gas line connected to the peripheral arc control gas flow path to supply the arc control gas to the peripheral arc control gas flow path, a peripheral line pressure control valve disposed on the peripheral arc control gas line to control pressure of the arc control gas, an intermediate arc control gas line connected to the intermediate arc control gas flow path to supply the arc control gas to the intermediate arc control gas flow path, an intermediate line pressure control valve disposed on the intermediate arc control gas line to control pressure of the arc control gas, a central arc control gas line connected to the central arc control gas flow path to supply the arc control gas to the central arc control gas flow path, and a central line pressure control valve disposed on the central arc control gas line to control pressure of the arc control gas.

In one example, the controller may control the peripheral line pressure control valve, the intermediate line pressure control valve, and the central line pressure control valve so that pressures of the arc control gas in the peripheral arc control gas flow path, the intermediate arc control gas flow path, and the central arc control gas flow path are controlled to be different from one another.

In one example, the substrate support device may further include a peripheral line heater disposed on the peripheral arc control gas line to control temperature of the arc control gas, an intermediate line heater disposed on the intermediate arc control gas line to control temperature of the arc control gas, and a central line heater disposed on the central arc control gas line to control temperature of the arc control gas.

In one example, the controller may control the peripheral line heater, the intermediate line heater, and the central line heater so that temperatures of the arc control gas in the peripheral arc control gas flow path, the intermediate arc control gas flow path, and the central arc control gas flow path are controlled to be different from one another.

In one example, the arc control gas supply unit may supply gas containing one selected from among hydrogen (H₂), xenon (Xe), and krypton (Kr) as the arc control gas.

In accordance with another aspect of the present disclosure, there is provided a method of preventing the occurrence of arcing, the method including performing a processing process on a substrate seated on a substrate support device, wherein an electrostatic-chuck plate and an electrode plate of the substrate support device are repeatedly heated and cooled due to the processing process, supplying arc control gas to a first arc control gas flow path formed between the electrostatic-chuck plate and the electrode plate, and controlling, by a controller, a pressure control valve to control pressure of the arc control gas flowing through the first arc control gas flow path to a set pressure, wherein the occurrence of arcing on a lower portion of the electrostatic-chuck plate is prevented through control of the pressure of the arc control gas.

In one example, in supplying the arc control gas, the arc control gas may be supplied to unit flow paths of the first arc control gas flow path formed respectively corresponding to a peripheral area, an intermediate area, and a central area of the electrostatic-chuck plate, and in controlling the pressure of the arc control gas, pressure of the arc control gas supplied to each of the unit flow paths of the first arc control gas flow path may be individually controlled.

In one example, in supplying the arc control gas, the arc control gas may be controlled in temperature and supplied to the first arc control gas flow path.

In one example, in supplying the arc control gas, the controller may control a heater based on an arcing occurrence profile to control temperature of the arc control gas, and in controlling the pressure of the arc control gas, the controller may control the pressure of the arc control gas in the first arc control gas flow path to a positive pressure based on the arcing occurrence profile.

In one example, supplying the arc control gas may include supplying the arc control gas to a second arc control gas flow path formed as a gap between the electrode plate and an insulator plate, and controlling the pressure of the arc control gas may include controlling, by the controller, the pressure control valve to control pressure of the arc control gas flowing through the second arc control gas flow path to a set pressure.

In accordance with a further aspect of the present disclosure, there is provided a substrate support device including an electrostatic-chuck plate configured to allow a substrate to be seated thereon and attract and support the substrate using electrostatic force, an electrode plate disposed under the electrostatic-chuck plate, a first arc control gas flow path formed between the electrostatic-chuck plate and the electrode plate, the first arc control gas flow path including a peripheral arc control gas flow path formed corresponding to a peripheral area of the electrostatic-chuck plate, an intermediate arc control gas flow path formed corresponding to an intermediate area of the electrostatic-chuck plate, and a central arc control gas flow path formed corresponding to a central area of the electrostatic-chuck plate, an insulator plate disposed under the electrode plate, a second arc control gas flow path formed as a gap between the electrode plate and the insulator plate, a plurality of arc control gas lines, each being connected to a respective one of the first arc control gas flow path and the second arc control gas flow path to individually supply arc control gas to a respective one of the first arc control gas flow path and the second arc control gas flow path, a plurality of pressure control valves, each being disposed on a respective one of the plurality of arc control gas lines to control pressure of the arc control gas, a plurality of heaters, each being disposed on a respective one of the plurality of arc control gas lines to control temperature of the arc control gas, an arc control gas supply unit configured to supply the arc control gas to the plurality of arc control gas lines, and a controller configured to control the plurality of pressure control valves based on an arcing occurrence profile to control pressure of the arc control gas flowing through each of the first arc control gas flow path and the second arc control gas flow path to a positive pressure, thereby preventing the occurrence of arcing.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIGS. 1 and 2 show a concept of preventing the occurrence of arcing according to the present disclosure;

FIG. 3 shows an embodiment of a substrate processing apparatus to which the present disclosure is applied;

FIG. 4 shows an embodiment of a substrate support device according to the present disclosure;

FIG. 5 shows an embodiment of an arc control gas flow path in the substrate support device according to the present disclosure;

FIG. 6 shows an embodiment of a pressure control valve applied to the substrate support device according to the present disclosure;

FIG. 7 shows another embodiment of the substrate support device according to the present disclosure;

FIG. 8 shows a graph of Paschen's law for arc control gas applicable to the present disclosure; and

FIGS. 9 and 10 show flowcharts showing an embodiment of a method of preventing the occurrence of arcing according to the present disclosure.

### DETAILED DESCRIPTION OF EXEMPLARY EMBODIMENTS

Hereinafter, exemplary embodiments of the present disclosure will be described in detail with reference to the accompanying drawings, but the present disclosure is not limited or restricted to the exemplary embodiments.

In order to sufficiently understand the present disclosure, the operational advantages of the present disclosure, and the objects to be accomplished by practice of the present disclosure, it is necessary to refer to the accompanying drawings illustrating the exemplary embodiments of the present disclosure and content contained in the drawings.

Further, the terminology used herein is for the purpose of describing particular embodiments only and is not intended to be limiting. As used herein, singular forms may be intended to include plural forms as well, unless the context clearly indicates otherwise. Further, in the following description of the embodiments, the terms “comprising,” “including,” or “having” are inclusive and therefore specify the presence of stated features, numbers, steps, operations, elements, components, or combinations thereof, but do not preclude the presence or addition of one or more other features, numbers, steps, operations, elements, components, or combinations thereof.

In the following description of the embodiments of the present disclosure, a detailed description of known configurations or functions incorporated herein will be omitted when it may unnecessarily obscure the subject matter of the present disclosure.

The present disclosure relates to technology for controlling discharge voltage by forming flow of arc control gas in an upper portion of a substrate support device and controlling the pressure of the arc control gas, thereby preventing the occurrence of arcing.

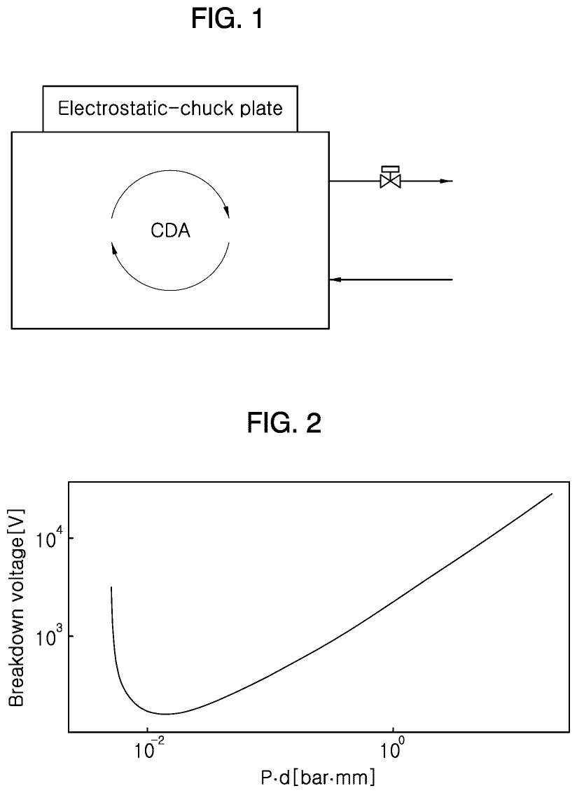

FIGS. 1 and 2 show a concept of preventing the occurrence of arcing according to the present disclosure.

In a substrate processing apparatus using plasma, a substrate is placed on a substrate support device, which attracts and supports the substrate using electrostatic force, and a process is performed. The substrate support device may include an electrostatic-chuck plate configured to attract and support the substrate using electrostatic force and an electrode plate disposed under the electrostatic-chuck plate. The electrode plate is provided therein with a refrigerant flow path to cool the substrate and the electrostatic-chuck plate, and refrigerant is injected into the refrigerant flow path in order to control temperature.

As the process progresses, the substrate support device experiences rapid temperature changes due to heating and cooling. Thus, the distance between electrodes and pressure change due to expansion and contraction of the substrate support device.

In particular, because a part of the substrate support device that comes into contact with refrigerant injected thereinto for cooling decreases rapidly in temperature, movement of electrons is restricted, leading to the occurrence of arcing.

In addition, the possibility of the occurrence of arcing further increases due to use of high power and low frequency and variation in structure of the substrate processing apparatus due to use of the refrigerant.

FIG. 2 is an arc discharge curve according to Paschen's law, in which the Y-axis represents breakdown voltage and the X-axis represents the product of the pressure of gas and the distance between electrodes.

According to Paschen's law, when pressure increases, the mean free path is shortened, and thus collision energy is reduced. Accordingly, ionization does not occur, and thus discharge does not occur.

Based on this principle, the present disclosure proposes technology capable of injecting arc control gas into a space under an electrostatic-chuck plate of a substrate support device and controlling pressure in accordance with flow of the gas, thereby preventing the occurrence of arcing on the lower portion of the electrostatic-chuck plate.

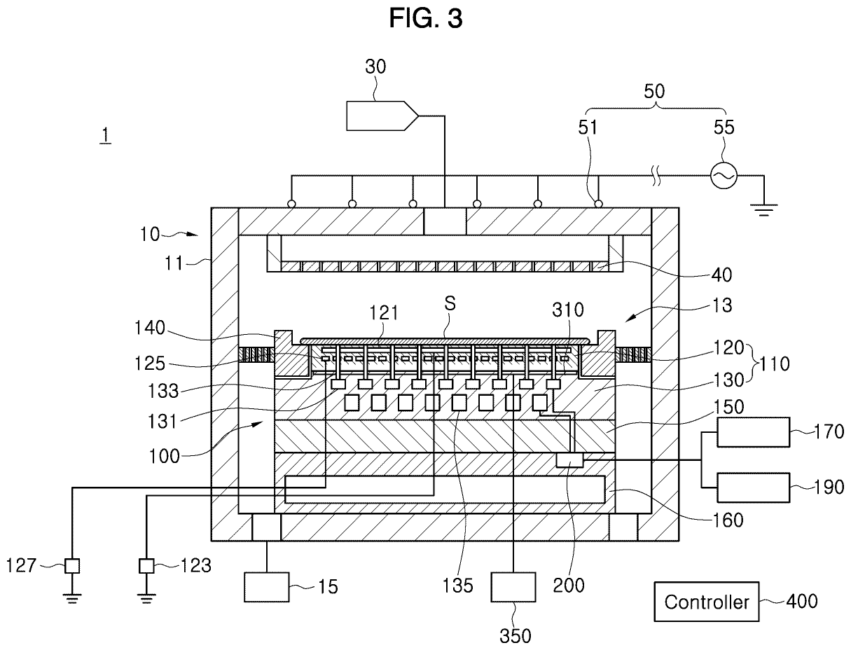

FIG. 3 shows an embodiment of a substrate processing apparatus to which a substrate support device according to the present disclosure is applied.

The substrate support device 100 according to the present disclosure may be applied to various substrate processing apparatuses used to process substrates, such as wafers or glass sheets, for manufacture of semiconductors, displays, etc.

The substrate processing apparatus 1 to which the substrate support device 100 according to the present disclosure is applied may be an apparatus that performs a series of substrate processing processes, including etching, ashing, deposition, and cleaning, in order to manufacture semiconductors. Hereinafter, a dry etcher that performs an etching process among substrate processing apparatuses using plasma will be described as the exemplary embodiment of the present disclosure.

In this embodiment, the substrate processing apparatus 1 may be configured to perform an etching process using plasma as a process of processing a substrate S. To this end, the substrate processing apparatus 1 may include a process chamber 10, a substrate support device 100, a process gas supply unit 30, a showerhead 40, and a plasma generation unit 50.

The process chamber 10 may have a substrate processing space 13 defined therein so as to be capable of being blocked from the outside, and the substrate S may be processed by plasma in the substrate processing space 13. The process chamber 10 may include a chamber main body 11. The chamber main body 11 may be formed to have the substrate processing space 13 therein. The chamber main body 11 may be made of metal. For example, the material of the chamber main body 11 may be aluminum (Al). The chamber main body 11 may be grounded.

At least one exhaust port, which communicates with the substrate processing space 13, may be provided in the bottom of the chamber main body 11, and an exhaust unit 15, which performs exhaust operation, may be connected to the exhaust port. The exhaust unit 15 may include an exhaust line connected to the exhaust port and a vacuum pump connected to the exhaust line. Due to the exhaust operation of the exhaust unit 15, pressure in the substrate processing space 13 may be lowered so that the substrate processing process performed under the vacuum atmosphere, and by-products generated during the substrate processing process or gas remaining in the substrate processing space 13 may be discharged to the outside.

The process gas supply unit 30 may supply process gas to the interior of the process chamber 10, and the plasma generation unit 50 may form an electromagnetic field in the process chamber 10 to excite the process gas supplied to the interior of the process chamber 10 to a plasma state.

The showerhead 40 may be disposed in an upper area in the substrate processing space 13, and may supply the process gas supplied from the process gas supply unit 30 to the substrate processing space 13 in a diffused manner.

The plasma generation unit 50 may excite the process gas in the substrate processing space 13 to a plasma state. In an example, the plasma generation unit 50 may include an antenna 51 provided on the upper side of the chamber 11 and a power supply 55.

The antenna 51 may be disposed parallel to an electrode plate 130 of an electrostatic chuck 110 with the substrate processing space 13 interposed therebetween. An electric field may be formed in the space between the two electrodes, and the process gas supplied to this space may be excited to a plasma state.

The substrate support device 100 may be mounted in the chamber main body 11. The substrate support device 100 may be disposed in a lower area in the substrate processing space 13, and may support the substrate S. The substrate support device 100 may be located at a height spaced upward from the bottom of the chamber main body 11.

The substrate support device 100 may include an electrostatic chuck 110 and a base plate 160.

The electrostatic chuck 110 may include an electrostatic-chuck plate 120 and an electrode plate 130.

The electrostatic-chuck plate 120 may chuck the substrate S using electrostatic force to support the same. The periphery of the electrostatic-chuck plate 120 may be surrounded by a focus ring 140.

The electrostatic-chuck plate 120 may be located on the top of the electrode plate 130. The electrostatic-chuck plate 120 may be provided as a disc-shaped dielectric substance. The substrate S may be placed on the upper surface of the electrostatic-chuck plate 120. In an example, a wafer may be placed as the substrate.

The upper surface of the electrostatic-chuck plate 120 may have a smaller radius than the substrate S. Therefore, the edge area of the substrate S may be located outside the electrostatic-chuck plate 120. The edge of the substrate S may be placed on the upper surface of the focus ring 140.

The focus ring 140 may be disposed around the edge area of the electrostatic-chuck plate 120. The focus ring 140 may have a ring shape, and may be disposed along the circumference of the electrostatic-chuck plate 120. The outer portion of the focus ring 140 may be provided to surround the edge area of the substrate S. The focus ring 140 may control the electromagnetic field so that the density of plasma is uniformly distributed over the entire area of the substrate S. Accordingly, plasma may be formed uniformly over the entire area of the substrate S, so that respective areas of the substrate S may be uniformly etched.

The electrostatic-chuck plate 120 may include therein an electrostatic electrode 121, a heater 125, and a supply flow path 133. The supply flow path 133 may be formed through the electrostatic-chuck plate 120 from the lower surface of the electrostatic-chuck plate 120 to the upper surface of the electrostatic-chuck plate 120. The supply flow path 133 may be provided in plural, and the plurality of supply flow paths 133 may be spaced apart from each other. The supply flow paths 133 may serve as passages through which a heat transfer medium is supplied to the lower surface of the substrate S.

The electrostatic electrode 121 may be electrically connected to a first power supply 123. The first power supply 123 may selectively supply direct current power to the electrostatic electrode 121. Electrostatic force may act between the electrostatic electrode 121 and the substrate S due to the current applied to the electrostatic electrode 121, and the substrate S may be adsorbed to the electrostatic-chuck plate 120 by the electrostatic force.

The heater 125 may be located below the electrostatic electrode 121. The heater 125 may be electrically connected to a second power supply 127. The heater 125 may generate resistive heat upon receiving current from the second power supply 127. The generated heat may be transferred to the substrate S through the electrostatic-chuck plate 120. The substrate S may be maintained at a predetermined temperature by the heat generated by the heater 125. The heater 125 may include a spiral-shaped coil.

The electrode plate 130 may be located under the electrostatic-chuck plate 120. The lower surface of the electrostatic-chuck plate 120 and the upper surface of the electrode plate 130 may be adhered to each other using an adhesive. The electrode plate 130 may be made of aluminum. The electrode plate 130 may have an area corresponding to the electrostatic-chuck plate 120, and may be adhered to the lower surface of the electrostatic-chuck plate 120. The electrode plate 130 may include a first flow path 131 and a second flow path 135 formed therein.

The first flow path 131 may serve as a passage through which a heat transfer medium circulates. The first flow path 131 may receive a heat transfer medium from a heat transfer medium supply unit 170 through a fluid supply block 200. In an example, the heat transfer medium may include helium (He).

The heat transfer medium such as helium (He) may be transferred to the supply flow path 133 through the first flow path 131 and may be supplied to the lower surface of the substrate S. The heat transfer medium such as helium may serve as a medium through which heat transferred from the plasma to the substrate S is transferred to the electrostatic-chuck plate 120.

The second flow path 135 may serve as a passage through which refrigerant circulates. The second flow path 135 may be formed below the first flow path 131. The second flow path 135 may receive coolant from a refrigerant supply unit 190 through the fluid supply block 200.

The coolant supplied to the second flow path 135 may circulate along the second flow path 135 to cool the electrode plate 130. As the electrode plate 130 is cooled, the electrostatic-chuck plate 120 and the substrate S may also be cooled, and thus the substrate S may be maintained at a predetermined temperature.

In an example, cryogenic refrigerant may be used as coolant, and various other refrigerants may also be used.

An insulator plate 150 may be located on the lower end of the electrostatic chuck 110 to increase the electrical distance between the electrode plate 130 and the base plate 160.

The base plate 160 may be located on the lower end of the insulator plate 150 to support the electrostatic chuck 110 and the insulator plate 150.

The base plate 160 may be provided with a fluid supply block 200 that supplies temperature control fluid and coolant to the electrostatic chuck 110. In this embodiment, the fluid supply block 200 is shown and described as being mounted in the base plate 160. However, in some embodiments, the fluid supply block 200 may be disposed in contact with the lower surface of the base plate 160.

A first arc control gas flow path 310 may be provided between the electrostatic-chuck plate 120 and the electrode plate 130. In the embodiment shown in FIG. 3, the first arc control gas flow path 310 is provided only under the electrostatic-chuck plate 120. However, the first arc control gas flow path 310 may extend to a region under the focus ring 140.

An arc control gas supply unit 350 may supply arc control gas to the first arc control gas flow path 310.

A controller 400 may control the pressure of the arc control gas flowing through the first arc control gas flow path 310, thereby preventing the occurrence of arcing.

In an example, arcing occurrence conditions according to performance of a process may be obtained through a process performance simulation or measurement during performance of an actual process using the substrate support device 100, and an arcing occurrence profile may be generated based on the obtained arcing occurrence conditions.

The controller 400 may store the arcing occurrence profile, may determine the arcing occurrence conditions according to performance of the process by the substrate support device 100, and may control the pressure of the arc control gas flowing through the first arc control gas flow path 310 in response to the conditions, thereby preventing the occurrence of arcing.

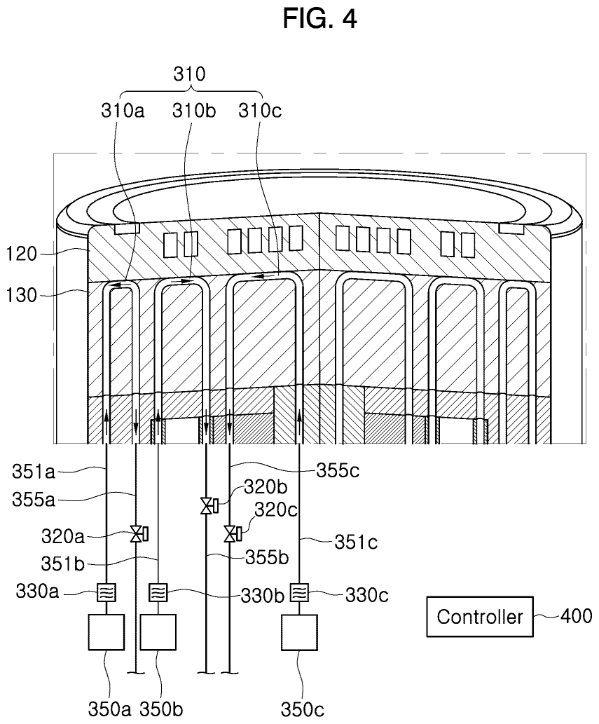

In relation to the supply and control of the arc control gas, FIG. 4 shows an embodiment of the substrate support device according to the present disclosure.

The first arc control gas flow path 310 may be formed as a gap between the electrostatic-chuck plate 120 and the electrode plate 130.

The first arc control gas flow path 310 may include a peripheral arc control gas flow path 310a formed corresponding to a peripheral area of the electrostatic-chuck plate 120, an intermediate arc control gas flow path 310b formed corresponding to an intermediate area of the electrostatic-chuck plate 120, and a central arc control gas flow path 310c formed corresponding to a central area of the electrostatic-chuck plate 120.

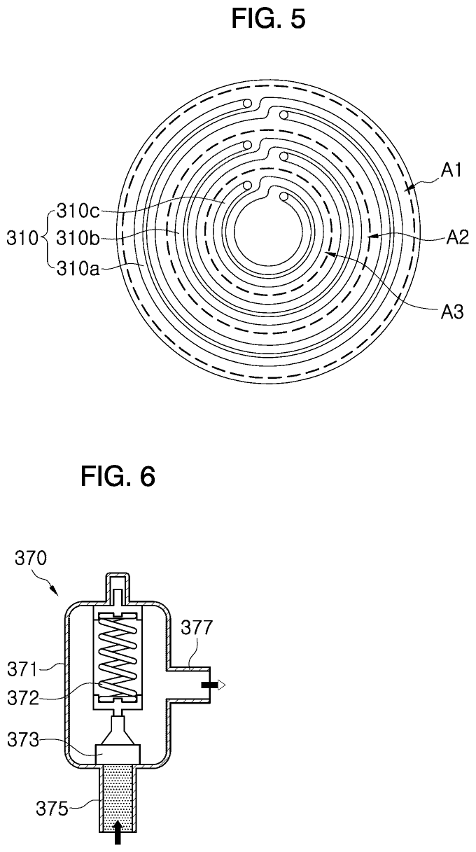

In relation to the first arc control gas flow path 310, FIG. 5 shows an embodiment of the arc control gas flow path in the substrate support device according to the present disclosure.

FIG. 5 shows the form of the arc control gas flow path 310 when viewed from above. Referring to FIG. 5, the peripheral arc control gas flow path 310a, the intermediate arc control gas flow path 310b, and the central arc control gas flow path 310c may be provided corresponding to the peripheral area A1, the intermediate area A2, and the central area A3 of the electrostatic-chuck plate 120, respectively.

The arc control gas may be supplied to the peripheral arc control gas flow path 310a, the intermediate arc control gas flow path 310b, and the central arc control gas flow path 310c so that the flow directions of the arc control gas flowing through adjacent ones of the flow paths 310a, 310b, and 310c are opposite each other. As needed, the arc control gas may be supplied to the peripheral arc control gas flow path 310a, the intermediate arc control gas flow path 310b, and the central arc control gas flow path 310c so that the arc control gas flows through the flow paths 310a, 310b, and 310c in the same direction.

Although the peripheral arc control gas flow path 310a, the intermediate arc control gas flow path 310b, and the central arc control gas flow path 310c are illustrated as having the same diameter, the diameters thereof may be formed to be different from one another as needed. In an example, the peripheral arc control gas flow path 310a, the intermediate arc control gas flow path 310b, and the central arc control gas flow path 310c may be formed such that the diameters thereof are gradually increased in that order.

Further, although the peripheral arc control gas flow path 310a, the intermediate arc control gas flow path 310b, and the central arc control gas flow path 310c are illustrated as being formed in a concentric shape, the number and shape of the flow paths formed corresponding to each area the electrostatic-chuck plate 120 may be variously modified.

Furthermore, although the electrostatic-chuck plate 120 of this embodiment is divided into three areas, i.e., the peripheral area, the intermediate area, and the central area, the electrostatic-chuck plate 120 may be divided into two areas or four or more areas as needed, and accordingly, the number and shape of the arc control gas flow paths may be modified.

The present embodiment will be successively explained with reference to FIG. 4.

The peripheral arc control gas flow path 310a may be connected to peripheral arc control gas lines 351a and 355a and may receive and discharge the arc control gas through the peripheral arc control gas lines 351a and 355a. The peripheral arc control gas lines 351a and 355a may include an inlet line 351a and an outlet line 355a.

A pressure control valve (not shown) and a pump (not shown) may be disposed on the inlet line 351a among the peripheral arc control gas lines in order to control the pressure of the arc control gas supplied. In addition, a heater 330a may be disposed on the inlet line 351a in order to heat the arc control gas supplied.

A pressure control valve 320a may be disposed on the outlet line 355a among the peripheral arc control gas lines in order to control the pressure of the gas flowing through the peripheral arc control gas flow path 310a.

The intermediate arc control gas flow path 310b may be connected to intermediate arc control gas lines 351b and 355b and may receive and discharge the arc control gas through the intermediate arc control gas lines 351b and 355b.

The intermediate arc control gas lines 351b and 355b may include an inlet line 351b and an outlet line 355b. A pressure control valve (not shown) and a pump (not shown) may be disposed on the inlet line 351b among the intermediate arc control gas lines in order to control the pressure of the arc control gas supplied. A heater 330b may be disposed on the inlet line 351b in order to heat the arc control gas supplied.

In addition, a pressure control valve 320b may be disposed on the outlet line 355b among the intermediate arc control gas lines in order to control the pressure of the gas flowing through the intermediate arc control gas flow path 310b.

The central arc control gas flow path 310c may be connected to central arc control gas lines 351c and 355c and may receive and discharge the arc control gas through the central arc control gas lines 351c and 355c. The central arc control gas lines 351c and 355c may include an inlet line 351c and an outlet line 355c. A pressure control valve (not shown) and a pump (not shown) may be disposed on the inlet line 351c in order to control the pressure of the arc control gas supplied. A heater 330c may be disposed on the inlet line 351c in order to heat the arc control gas supplied. In addition, a pressure control valve 320c may be disposed on the outlet line 355c in order to control the pressure of the gas flowing through the central arc control gas flow path 310c.

Arc control gas supply units 350a, 350b, and 350c may be provided to supply the arc control gas to the peripheral arc control gas flow path 310a, the intermediate arc control gas flow path 310b, and the central arc control gas flow path 310c.

Each of the arc control gas supply units 350a, 350b, and 350c may be connected to a respective one of the peripheral arc control gas flow path 310a, the intermediate arc control gas flow path 310b, and the central arc control gas flow path 310c. Alternatively, there may be provided an integrated arc control gas supply unit.

The controller 400 may individually control the pressure of the arc control gas flowing through each of the peripheral arc control gas flow path 310a, the intermediate arc control gas flow path 310b, and the central arc control gas flow path 310c.

In an example, the controller 400 may control the arc control gas supply units 350a, 350b, and 350c to control the amount of arc control gas supplied to each of the peripheral arc control gas flow path 310a, the intermediate arc control gas flow path 310b, and the central arc control gas flow path 310c.

In an example, the controller 400 may control the pressure control valves 320a, 320b, and 320c respectively corresponding to the peripheral arc control gas flow path 310a, the intermediate arc control gas flow path 310b, and the central arc control gas flow path 310c to individually control the pressure of the arc control gas flowing through each of the peripheral arc control gas flow path 310a, the intermediate arc control gas flow path 310b, and the central arc control gas flow path 310c.

The pressure of the arc control gas flowing through each of the peripheral arc control gas flow path 310a, the intermediate arc control gas flow path 310b, and the central arc control gas flow path 310c may be controlled to a positive pressure. At this time, the pressures of the arc control gas flowing through the flow paths 310a, 310b, and 310c may be controlled to be different from one another.

In an example, the controller 400 may control the temperatures of the arc control gas supplied to the peripheral arc control gas flow path 310a, the intermediate arc control gas flow path 310b, and the central arc control gas flow path 310c. At this time, the temperatures of the arc control gas supplied to the flow paths 310a, 310b, and 310c may be controlled to be different from one another.

Various types of valves may be used as the pressure control valves 320a, 320b, and 320c for controlling the pressures of the arc control gas flowing through the peripheral arc control gas flow path 310a, the intermediate arc control gas flow path 310b, and the central arc control gas flow path 310c. FIG. 6 shows an embodiment of the pressure control valve applied to the substrate support device according to the present disclosure.

In the embodiment shown in FIG. 6, the pressure control valve is implemented as a relief valve 370.

If pressure higher than a set value is applied to the arc control gas flowing through the peripheral arc control gas flow path 310a, the intermediate arc control gas flow path 310b, and the central arc control gas flow path 310c, the relief valve 370 may operate to relieve overpressure.

In detail, in the process of controlling the pressure of the arc control gas flowing through each of the peripheral arc control gas flow path 310a, the intermediate arc control gas flow path 310b, and the central arc control gas flow path 310c to a positive pressure, if excessively high pressure is applied to the arc control gas, it may adversely affect the stability of the substrate support device 100. Therefore, the relief valve 370 may be provided in order to prevent the pressure from exceeding the set value.

In the relief valve 370, if pressure higher than the set value is applied to the gas flowing through a conduit 375, the pressure is exerted on a valve seat 373 and presses a spring 372. Thus, the relief valve 370 is opened, and the gas is discharged through a discharge path 377. In this way, the relief valve 370 may reduce the pressure. However, the relief valve 370 is merely exemplary, and various other types of relief valves may be employed.

As described above, according to the present disclosure, in the process of controlling the pressure of the arc control gas flowing through each of the peripheral arc control gas flow path 310a, the intermediate arc control gas flow path 310b, and the central arc control gas flow path 310c to a positive pressure, the pressure may increase to a certain level or higher. However, when overpressure higher than a set value occurs, the pressure control valve 320a, 320b, and 320c may reduce the pressure.

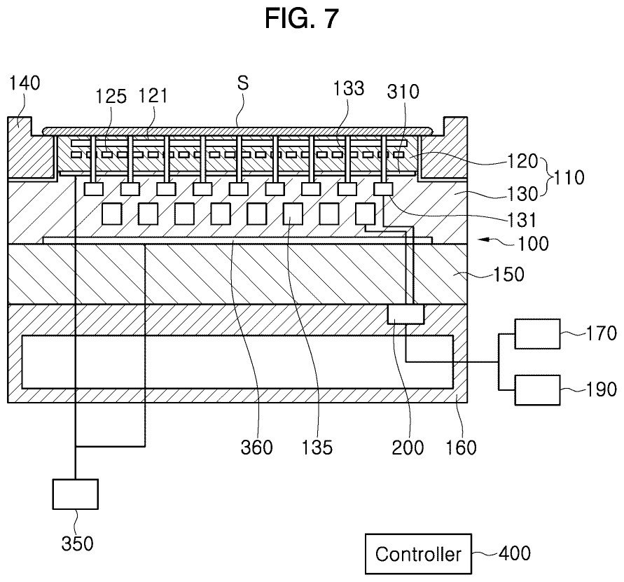

The substrate support device of the embodiment may further include a second arc control gas flow path in addition to the first arc control gas flow path described above. Therefore, it is possible to more effectively prevent the occurrence of arcing by controlling the pressure of the arc control gas flowing through each of the first arc control gas flow path and the second arc control gas flow path. In this regard, FIG. 7 shows another embodiment of the substrate support device according to the present disclosure.

In describing the embodiment shown in FIG. 7, descriptions of the same components as those of the embodiment described above will be omitted or given in brief.

As described above, the first arc control gas flow path 310 may be provided between the electrostatic-chuck plate 120 and the electrode plate 130.

In addition, a second arc control gas flow path 360 may be provided between the electrode plate 130 and the insulator plate 150.

The second arc control gas flow path 360 may be formed as a gap between the electrode plate 130 and the insulator plate 150.

The second arc control gas flow path 360 may be formed as a single flow path between the electrode plate 130 and the insulator plate 150.

Alternatively, similar to the above-described first arc control gas flow path 310, which includes a plurality of unit flow paths formed respectively corresponding to the peripheral area, the intermediate area, and the central area of the electrostatic-chuck plate 120, the second arc control gas flow path 360 may include a plurality of unit flow paths formed respectively corresponding to the peripheral area, the intermediate area, and the central area of the electrode plate 130. Further, the number and shape of the unit flow paths of the second arc control gas flow path 360 formed corresponding to each area may be set differently from those of the unit flow paths of the first arc control gas flow path 310 formed corresponding to each area.

An arc control gas supply unit 350 may supply arc control gas to the first arc control gas flow path 310 and the second arc control gas flow path 360.

An arc control gas supply unit for the first arc control gas flow path 310 and an arc control gas supply unit for the second arc control gas flow path 360 may be provided separately from each other.

The arc control gas may be supplied from the arc control gas supply unit 350 through an arc control gas line connected to the second arc control gas flow path 360. The arc control gas line may include an inlet line and an outlet line.

In addition, a pressure control valve, a pump, and a heater may be disposed on the arc control gas line in order to control the pressure, amount, and temperature of the arc control gas supplied to the second arc control gas flow path 360.

The controller 400 may control the amount, temperature, and pressure of the arc control gas supplied to each of the first arc control gas flow path 310 and the second arc control gas flow path 360, and may control the pressure of the arc control gas flowing through each of the flow paths 310 and 360.

The controller 400 may control the pressure of the arc control gas flowing through each of the first arc control gas flow path 310 and the second arc control gas flow path 360 to a positive pressure based on the arcing occurrence profile generated based on the arc occurrence conditions. Preferably, the controller 400 may control the pressure of the arc control gas flowing through the first arc control gas flow path 310 and the pressure of the arc control gas flowing through the second arc control gas flow path 360 to be different from each other.

Since the division of the second arc control gas flow path 360 for the areas of the electrode plate 130 and control of the pressure and temperature of the arc control gas supplied to the second arc control gas flow path 360 are similar to the division of the first arc control gas flow path 310 for the areas of the electrostatic-chuck plate 120 and control of the pressure and temperature of the arc control gas supplied to the first arc control gas flow path 310, detailed description thereof will be omitted.

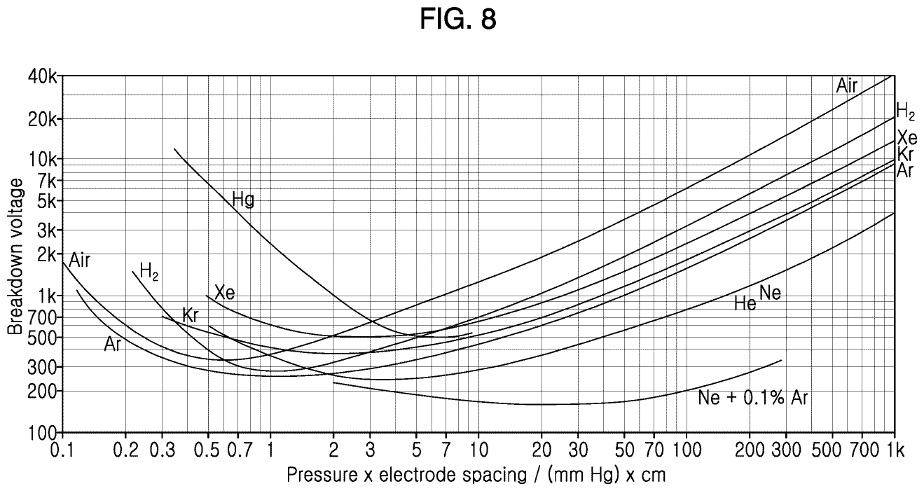

FIG. 8 shows a graph of Paschen's law for the arc control gas applicable to the present disclosure.

In the present disclosure, clean dry air (CDA) may be used as the arc control gas.

As shown in FIG. 8, air may function as the most adequate arc control gas.

In addition to air, gas containing one selected from among hydrogen (H₂), xenon (Xe), and krypton (Kr) may also be used as the arc control gas.

In addition, the present disclosure proposes a method of preventing the occurrence of arcing through the substrate support device described above. Hereinafter, an embodiment of the method of preventing the occurrence of arcing according to the present disclosure will be described.

Since the method of preventing the occurrence of arcing according to the present disclosure is implemented through the substrate support device according to the present disclosure described above, the method will be described with reference to the above-described embodiment of the substrate support device.

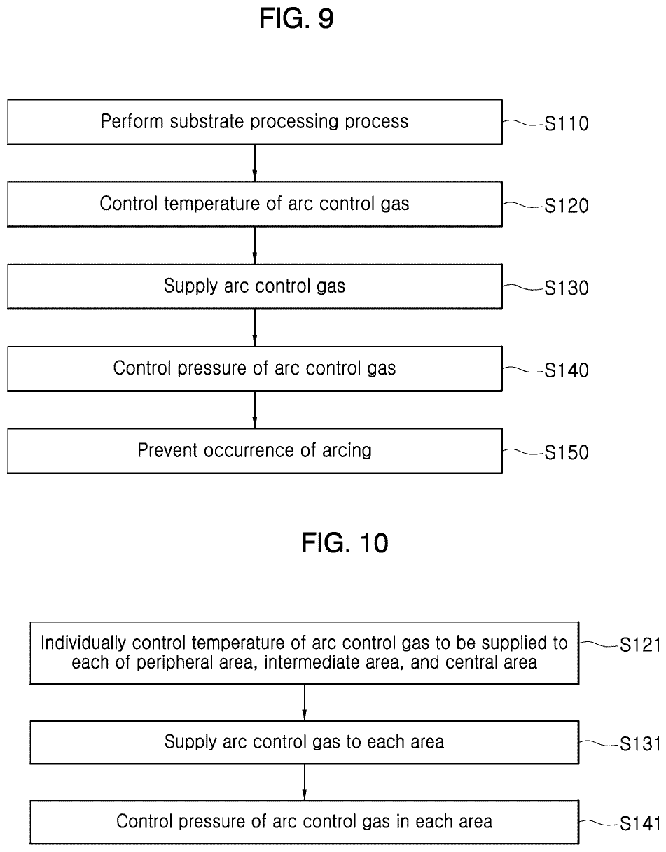

FIGS. 9 and 10 show flowcharts showing an embodiment of the method of preventing the occurrence of arcing according to the present disclosure.

When a substrate processing process is performed on a substrate adsorbed to and seated on the substrate support device 100 of the substrate processing apparatus 1 (S110), the electrostatic-chuck plate 120 and the electrode plate 130 of the substrate support device 100 are repeatedly heated and cooled.

As the process progresses, the substrate support device 100 experiences rapid temperature changes. Thereby, the distance between electrodes and pressure change due to expansion and contraction of the substrate support device 100, which may cause arcing.

The controller 400 may determine the state of the substrate support device 100 in accordance with performance of the process based on the arcing occurrence profile, and may selectively supply the arc control gas to the first arc control gas flow path 310 and the second arc control gas flow path 360 in order to prevent the occurrence of arcing (S130).

Before supplying the arc control gas to at least one of the first arc control gas flow path 310 or the second arc control gas flow path 360, the controller 400 may control the temperature of the arc control gas by heating the arc control gas (S120).

As the arc control gas is supplied to at least one of the first arc control gas flow path 310 or the second arc control gas flow path 360, the pressure of the arc control gas flowing through the first arc control gas flow path 310 or the second arc control gas flow path 360 may be increased.

The controller 400 may control the pressure of the arc control gas flowing through at least one of the first arc control gas flow path 310 or the second arc control gas flow path 360 to a positive pressure (S140).

Further, if the pressure in at least one of the first arc control gas flow path 310 or the second arc control gas flow path 360 increases to a certain level or higher, the controller 400 may control the pressure of the arc control gas flowing through at least one of the first arc control gas flow path 310 or the second arc control gas flow path 360 to a set value or lower through the pressure control valve.

The pressure of the arc control gas flowing through at least one of the first arc control gas flow path 310 or the second arc control gas flow path 360 may be controlled to a positive pressure, whereby the occurrence of arcing on the lower portion of the electrostatic chuck of the substrate support device 100 may be prevented (S150).

Furthermore, the arc control gas may be supplied to each area and the pressure thereof may be controlled. This will be described with reference to FIG. 10. Because the processes shown in FIG. 10 are detailed processes of the embodiment shown in FIG. 9, descriptions of the same processes as those of the embodiment shown in FIG. 9 will be omitted.

At least one of the first arc control gas flow path 310 or the second arc control gas flow path 360 may be divided into a peripheral area, an intermediate area, and a central area, and the controller 400 may individually control the temperature of the arc control gas to be supplied to each of the areas of at least one of the first arc control gas flow path 310 or the second arc control gas flow path 360 (S121).

In addition, the controller 400 may supply the arc control gas to each of the areas of at least one of the first arc control gas flow path 310 or the second arc control gas flow path 360 (S131).

The controller 400 may control the pressure of the arc control gas flowing through each of the areas of at least one of the first arc control gas flow path 310 or the second arc control gas flow path 360 to a positive pressure (S141). If the pressure in a certain flow path increases to a certain level or higher, the controller 400 may control the pressure control valve to control the pressure of the arc control gas flowing through the corresponding flow path to a set value or lower.

As described above, according to the present disclosure, discharge voltage is controlled by forming flow of arc control gas in the upper portion of the substrate support device and controlling the pressure of the arc control gas, thereby preventing the occurrence of arcing.

In particular, the occurrence of arcing on the electrode plate and various other components disposed under the electrostatic-chuck plate may be prevented, and condensation in the flow paths in the substrate support device may be prevented.

As is apparent from the above description, according to the present disclosure, it is possible to control discharge voltage by forming flow of arc control gas in an upper portion of a substrate support device and controlling the pressure of the arc control gas, thereby preventing the occurrence of arcing.

In particular, it is possible to prevent not only the occurrence of arcing on an electrode plate and various other components disposed under an electrostatic-chuck plate but also condensation in flow paths in the substrate support device.

The effects achievable through the present disclosure are not limited to the above-mentioned effects, and other effects not mentioned herein will be clearly understood by those skilled in the art from the above description.

It will be apparent to those skilled in the art that various changes in form and details may be made without departing from the essential characteristics of the disclosure set forth herein. Accordingly, the above detailed description is not intended to be construed to limit the disclosure in all aspects and to be considered by way of example. The scope of the disclosure should be determined by reasonable interpretation of the appended claims and all equivalent modifications made without departing from the disclosure should be included in the following claims.

What is claimed is:

1. A substrate support device comprising:
an electrostatic-chuck plate configured to allow a substrate to be seated thereon and attract and support the substrate using electrostatic force;
an electrode plate disposed under the electrostatic-chuck plate;
a first arc control gas flow path formed between the electrostatic-chuck plate and the electrode plate;
an arc control gas supply unit configured to supply an arc control gas to the first arc control gas flow path; and
a controller configured to control a pressure of the arc control gas flowing through the first arc control gas flow path to prevent occurrence of arcing.

2. The substrate support device as claimed in claim 1,
wherein the electrode plate has a heat transfer medium path formed therein to supply a heat transfer medium to a lower surface of the substrate and a cooling path formed therein to allow refrigerant for cooling of the substrate and the electrostatic-chuck plate to flow therethrough.

3. The substrate support device as claimed in claim 1,
wherein the arc control gas supply unit supplies clean dry air (CDA) as the arc control gas.

4. The substrate support device as claimed in claim 1, further comprising:
an insulator plate disposed under the electrode plate; and
a second arc control gas flow path formed between the electrode plate and the insulator plate,
wherein the arc control gas supply unit supplies an arc control gas to the second arc control gas flow path, and
wherein the controller controls a pressure of the arc control gas flowing through the second arc control gas flow path to prevent occurrence of arcing.

5. The substrate support device as claimed in claim 1, further comprising:
an arc control gas line connected to the first arc control gas flow path to supply the arc control gas from the arc control gas supply unit to the first arc control gas flow path; and
a pressure control valve disposed on the arc control gas line to control the pressure of the arc control gas flowing through the first arc control gas flow path.

6. The substrate support device as claimed in claim 5,
wherein the pressure control valve comprises a relief valve.

7. The substrate support device as claimed in claim 5, further comprising a heater disposed on the arc control gas line to control a temperature of the arc control gas.

8. The substrate support device as claimed in claim 7,
wherein the controller controls the pressure control valve and the heater based on an arcing occurrence profile so that the arc control gas is controlled in temperature and supplied to the first arc control gas flow path and so that the pressure of the arc control gas flowing through the first arc control gas flow path is controlled to a positive pressure.

9. The substrate support device as claimed in claim 1,
wherein the first arc control gas flow path comprises:
a peripheral arc control gas flow path formed corresponding to a peripheral area of the electrostatic-chuck plate;
an intermediate arc control gas flow path formed corresponding to an intermediate area of the electrostatic-chuck plate; and
a central arc control gas flow path formed corresponding to a central area of the electrostatic-chuck plate.

10. The substrate support device as claimed in claim 9, further comprising:
a peripheral arc control gas line connected to the peripheral arc control gas flow path to supply the arc control gas to the peripheral arc control gas flow path;
a peripheral line pressure control valve disposed on the peripheral arc control gas line to control the pressure of the arc control gas flowing through the first arc control gas flow path;
an intermediate arc control gas line connected to the intermediate arc control gas flow path to supply the arc control gas to the intermediate arc control gas flow path;
an intermediate line pressure control valve disposed on the intermediate arc control gas line to control the pressure of the arc control gas flowing through the first arc control gas flow path;
a central arc control gas line connected to the central arc control gas flow path to supply the arc control gas to the central arc control gas flow path; and
a central line pressure control valve disposed on the central arc control gas line to control the pressure of the arc control gas flowing through the first arc control gas flow path.

11. The substrate support device as claimed in claim 10,
wherein the controller controls the peripheral line pressure control valve, the intermediate line pressure control valve, and the central line pressure control valve so that pressures of the arc control gas in the peripheral arc control gas flow path, the intermediate arc control gas flow path, and the central arc control gas flow path are controlled to be different from one another.

12. The substrate support device as claimed in claim 10, further comprising:
a peripheral line heater disposed on the peripheral arc control gas line to control a temperature of the arc control gas flowing through the first arc control gas flow path;
an intermediate line heater disposed on the intermediate arc control gas line to control the temperature of the arc control gas flowing through the first arc control gas flow path; and
a central line heater disposed on the central arc control gas line to control the temperature of the arc control gas flowing through the first arc control gas flow path.

13. The substrate support device as claimed in claim 12,
wherein the controller controls the peripheral line heater, the intermediate line heater, and the central line heater so that temperatures of the arc control gas in the peripheral arc control gas flow path, the intermediate arc control gas flow path, and the central arc control gas flow path are controlled to be different from one another.

14. The substrate support device as claimed in claim 1,
wherein the arc control gas supply unit supplies gas containing one selected from among hydrogen (H₂), xenon (Xe), and krypton (Kr) as the arc control gas.

15. A method of preventing occurrence of arcing, the method comprising:
performing a processing process on a substrate seated on a substrate support device, wherein an electrostatic-chuck plate and an electrode plate of the substrate support device are repeatedly heated and cooled due to the processing process;
supplying arc control gas to a first arc control gas flow path formed between the electrostatic-chuck plate and the electrode plate; and
controlling, by a controller, a pressure control valve to control a pressure of the arc control gas flowing through the first arc control gas flow path to a set pressure,
wherein occurrence of arcing on a lower portion of the electrostatic-chuck plate is prevented through control of the pressure of the arc control gas.

16. The method as claimed in claim 15,
wherein, in supplying the arc control gas, the arc control gas is supplied to unit flow paths of the first arc control gas flow path formed respectively corresponding to a peripheral area, an intermediate area, and a central area of the electrostatic-chuck plate, and
wherein, in controlling the pressure of the arc control gas, a pressure of the arc control gas supplied to each of the unit flow paths of the first arc control gas flow path is individually controlled.

17. The method as claimed in claim 15,
wherein, in supplying the arc control gas, the arc control gas is controlled in temperature and supplied to the first arc control gas flow path.

18. The method as claimed in claim 15,
wherein, in supplying the arc control gas, the controller controls a heater based on an arcing occurrence profile to control a temperature of the arc control gas, and
wherein, in controlling the pressure of the arc control gas, the controller controls the pressure of the arc control gas in the first arc control gas flow path to a positive pressure based on the arcing occurrence profile.

19. The method claimed in claim 15,
wherein supplying the arc control gas comprises supplying the arc control gas to a second arc control gas flow path formed as a gap between the electrode plate and an insulator plate, and
wherein controlling the pressure of the arc control gas comprises controlling, by the controller, the pressure control valve to control a pressure of the arc control gas flowing through the second arc control gas flow path to a set pressure.

20. A substrate support device comprising:
an electrostatic-chuck plate configured to allow a substrate to be seated thereon and attract and support the substrate using electrostatic force;
an electrode plate disposed under the electrostatic-chuck plate;
a first arc control gas flow path formed between the electrostatic-chuck plate and the electrode plate, the first arc control gas flow path comprising a peripheral arc control gas flow path formed corresponding to a peripheral area of the electrostatic-chuck plate, an intermediate arc control gas flow path formed corresponding to an intermediate area of the electrostatic-chuck plate, and a central arc control gas flow path formed corresponding to a central area of the electrostatic-chuck plate;
an insulator plate disposed under the electrode plate;
a second arc control gas flow path formed as a gap between the electrode plate and the insulator plate;
a plurality of arc control gas lines, each being connected to a respective one of the first arc control gas flow path and the second arc control gas flow path to individually supply arc control gas to the respective one of the first arc control gas flow path and the second arc control gas flow path;
a plurality of pressure control valves, each being disposed on a respective one of the plurality of arc control gas lines to control pressure of the arc control gas supplied to the respective one of the first and second control gas flow paths;
a plurality of heaters, each being disposed on the respective one of the plurality of arc control gas lines to control a temperature of the arc control gas;
an arc control gas supply unit configured to supply the arc control gas to the plurality of arc control gas lines; and
a controller configured to control the plurality of pressure control valves based on an arcing occurrence profile to control the pressure of the arc control gas flowing through the respective one of the first arc control gas flow path and the second arc control gas flow path to a positive pressure, thereby preventing occurrence of arcing.
